(19) United States
(12) Patent Application Publication
(10) Pub. No.: US 2015/0279924 A1
(43) Pub. Date: Oct. 1, 2015

(54) MIM CAPACITOR AND METHOD OF MANUFACTURING MIM CAPACITOR

(71) Applicant: KABUSHIKI KAISHA TOSHIBA, Tokyo (JP)

(72) Inventor: Keiichi MATSUSHITA, Ota Tokyo (JP)

(21) Appl. No.: 14/669,283

(22) Filed: Mar. 26, 2015

(30) Foreign Application Priority Data
Mar. 28, 2014 (JP) 2014-068409

(51) Int. Cl. H01L 49/02; H01L 23/00

(52) U.S. Cl. CPC H01L 28/65; H01L 28/60; H01L 24/43; H01L 24/45; H01L 2224/45144; H01L 2924/01079; H01L 2924/01078; H01L 2924/01022; H01L 2924/206

(57) ABSTRACT

An MIM capacitor includes a lower electrode on a surface of a semiconductor substrate, an insulating film on the surface of the semiconductor substrate and a portion of the lower electrode, an upper electrode on a surface of a portion of the insulating film above the lower electrode, and an air bridge wire connected only to a central region of a surface of the upper electrode so as to be spaced above an end region of the surface of the upper electrode.

### CROSS-REFERENCE TO RELATED APPLICATION

This application is based upon and claims the benefit of priority from Japanese Patent Application No. 2014-068409, filed Mar. 28, 2014, the entire contents of which are incorporated herein by reference.

### FIELD

Embodiments described herein relate generally to metal-insulator-metal (MIM) capacitors.

### BACKGROUND

An IC for handling microwave signals that is used in the communications field or the like generally includes a metal-insulator-metal (MIM) capacitor. The existing MIM capacitor is connected to an air bridge wire at an end of an upper electrode and is connected, via the air bridge wire, to other elements, wires, and so forth included in the IC.

In such an existing MIM capacitor, if the sizes of the upper electrode and a lower electrode are increased to ensure large capacity, the stress, such as thermal stress, which is put on the upper electrode and the lower electrode is increased. The stress is concentrated on an end of the MIM capacitor, including the end of the upper electrode to which the air bridge wire is connected. As a result, a crack appears in an insulating film that is included in the end of the MIM capacitor, the insulating film whose strength is lower than the strength of the upper electrode and the lower electrode, and manufacturing yields are reduced.

### DESCRIPTION OF THE DRAWINGS

FIG. 1 is a sectional view of principal portions of an MIM capacitor according to an embodiment;

FIG. 2 is a plan view of the MIM capacitor illustrated in FIG. 1, the MIM capacitor viewed from above;

FIG. 3 is a sectional view for illustrating a method for producing the MIM capacitor according to the embodiment, the sectional view corresponding to FIG. 1;

FIG. 4 is a sectional view for illustrating the method for producing the MIM capacitor according to the embodiment, the sectional view corresponding to FIG. 1;

FIG. 5 is a sectional view for illustrating the method for producing the MIM capacitor according to the embodiment, the sectional view corresponding to FIG. 1;

FIG. 6 is a sectional view for illustrating the method for producing the MIM capacitor according to the embodiment, the sectional view corresponding to FIG. 1; and

FIG. 7 is a sectional view for illustrating the method for producing the MIM capacitor according to the embodiment, the sectional view corresponding to FIG. 1.

### DETAILED DESCRIPTION

An exemplary embodiment provides an MIM capacitor having a high manufacturing yield.

In general, according to one embodiment, an MIM capacitor includes: a lower electrode on a surface of a semiconductor substrate, an insulating film on the surface of the semiconductor substrate and a portion of the lower electrode, an upper electrode on a surface of a portion of the insulating film above the lower electrode, and an air bridge wire that connected only to a central region of a surface of the upper electrode so as to be spaced above an end region of the surface of the upper electrode.

Hereinafter, an MIM capacitor according to an embodiment will be described in detail with reference to the drawings.

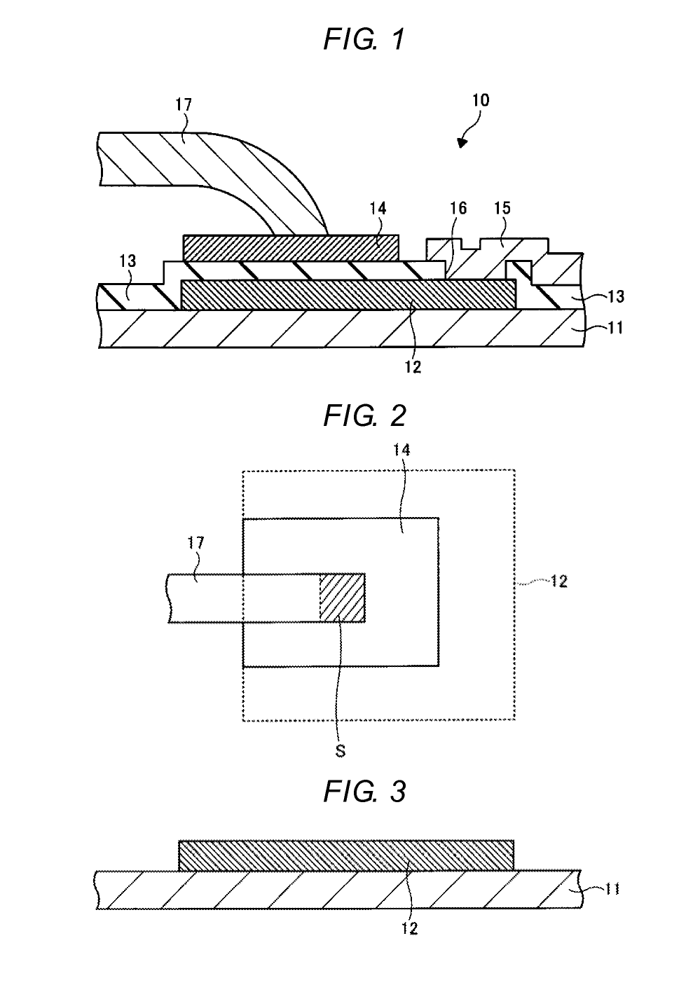

FIG. 1 is a sectional view of principal portions of an MIM capacitor 10 according to an embodiment. The MIM capacitor 10 illustrated in FIG. 1 is provided on a surface of a semiconductor substrate 11 formed of a material, such as Si, GaN, or GaAs, and includes a lower electrode 12, an insulating film 13, and an upper electrode 14.

As shown, the lower electrode 12 made of metal is provided on the surface of the semiconductor substrate 11. The lower electrode 12 is formed of a plurality of stacked metal films, for example, and has a thickness of about 600 nm to 1 μm. In the MIM capacitor 10 according to the embodiment, the lower electrode 12 is formed by stacking Au film, Pt film, and Ti film in this order on the substrate 11.

Moreover, on the surface of the semiconductor substrate 11, the insulating film 13 is formed to cover the lower electrode 12. This insulating film 13 is formed of a SiN film, a SiO₂ film, or the like, and has a thickness of about 100 nm to 300 nm.

In addition, the upper electrode 14 made of metal is provided in a position on the surface of the insulating film 13 corresponding to a part above the lower electrode 12. The upper electrode 14 has a smaller area than the lower electrode 12 and has a thickness of about 600 nm to 1 μm, which is obtained as a result of, for example, a plurality of metal films being stacked. In the MIM capacitor 10 according to the embodiment, the upper electrode 14 is formed by stacking Ti film, Pt film, and Au film in this order on the insulating film.

Moreover, a wire 15 is connected to the above-described lower electrode 12. In a part of the above-described insulating film 13 above the lower electrode 12, an opening 16 that exposes the lower electrode 12 is provided. The wire 15 is provided on the surface of the insulating film 13 so that one end of the wire 15 is connected to the lower electrode 12 through the opening 16. This wire 15 is formed of Au, for example, and has a thickness of about 100 nm to 300 nm, which is comparable in thickness to the insulating film 13.

In addition, an air bridge wire 17 is connected to the above-described upper electrode 14. The air bridge wire 17 is provided so that one end thereof is connected to the upper electrode 14 and the other end thereof is spaced above the surface of the insulating film 13. The air bridge wire 17 is formed of Au, for example.

FIG. 2 is a plan view of the above-described MIM capacitor 10 viewed from above . For clarity, the insulating film 13 is not illustrated in FIG. 2, and the lower electrode 12 is indicated by a dotted line. As illustrated in FIG. 2, a contact region S between the end of the air bridge wire 17 and the surface of the upper electrode 14 is provided only in a central region of the surface of the upper electrode 14. That is, the air bridge wire 17 is connected only to the central region of the surface of the upper electrode 14 and is spaced above an end region of the surface of the upper electrode 14 (FIG. 1).

Incidentally, even when the air bridge wire 17 is viewed from the lower electrode 12, the air bridge wire 17 is connected to the surface of the upper electrode 14 above a central region of the lower electrode 12.

FIGS. 3 to 7 are sectional views for illustrating a method for producing the MIM capacitor 10 described above, the sectional views corresponding to FIG. 1. Hereinafter, with reference to FIGS. 3 to 7, the method for producing the MIM capacitor 10 according to the embodiment will be described.

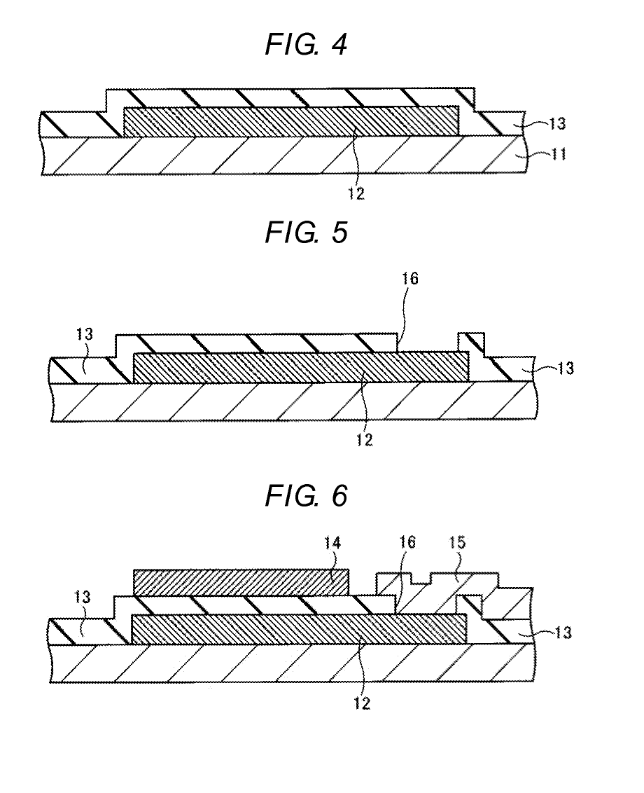

First, as illustrated in FIG. 3, a lower electrode 12 is formed in a predetermined region on the surface of a semiconductor substrate 11. Then, as illustrated in FIG. 4, an insulating film 13 is formed on the surface of the semiconductor substrate 11 to cover the lower electrode 12.

Next, as depicted in FIG. 5, an opening 16 is formed in a part of the insulating film 13 so that a part of the lower electrode 12 is exposed.

Next, as illustrated in FIG. 6, an upper electrode 14 is formed on the surface of the insulating film 13 on the lower electrode 12, and a wire 15 is formed on the surface of the insulating film 13 so that the wire 15 is connected to the lower electrode 12 exposed through the opening 16 of the insulating film 13. The upper electrode 14 and the wire 15 may be formed at the same time or may be formed in separate processes.

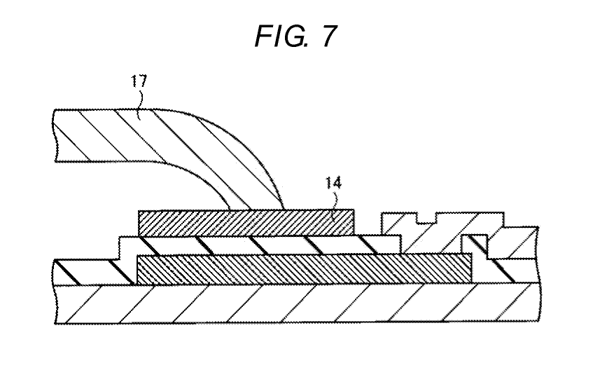

Lastly, as illustrated in FIG. 7, an air bridge wire 17 is formed so that an end thereof is connected only to a central region of the surface of the upper electrode 14. In this manner, the MIM capacitor 10 illustrated in FIGS. 1 and 2 is produced.

In the MIM capacitor 10 according to the embodiment described above, the air bridge wire 17 is connected only to the central region of the surface of the upper electrode 14. Therefore, even when thermal stress, for example, is applied to the MIM capacitor 10 including the air bridge wire 17, this stress is distributed across the MIM capacitor 10, which makes it possible to suppress the occurrence of a crack in the insulating film 13 of the MIM capacitor 10. As a result, it is possible to provide the MIM capacitor 10 having a high manufacturing yield.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A metal-insulator-metal (MIM) capacitor, comprising:
a lower electrode on a surface of a semiconductor substrate;
an insulating film on the surface of the semiconductor substrate and a portion of the lower electrode;
an upper electrode on a surface of a portion of the insulating film above the lower electrode; and
an air bridge wire connected only to a central region of a surface of the upper electrode so as to be spaced above an end region of the surface of the upper electrode.

2. The MIM capacitor according to claim 1, further comprising:
an opening in the insulating film that exposes part of a surface of the lower electrode, and
a wire connected to the lower electrode through the opening.

3. The MIM capacitor according to claim 1, wherein the central region of the surface of the upper electrode is generally aligned with a central region of a surface of the lower electrode.

4. The MIM capacitor according to claim 1, wherein each of the upper electrode and the lower electrode comprises a plurality of stacked metal films.

5. The MIM capacitor according to claim 4, wherein the lower electrode comprises Au film, Pt film, and Ti film in this order on the substrate.

6. The MIM capacitor according to claim 5, wherein the upper electrode comprises Ti film, Pt film, and Au film in this order on the insulating film.

7. The MIM capacitor according to claim 1, wherein each of the upper electrode and the lower electrode has a thickness of about 600 nm to 1 pm.

8. The MIM capacitor according to claim 1, wherein the wire has a thickness of about 100 nm to 300 nm.

9. The MIM capacitor according to claim 1, wherein the air bridge wire comprises Au.

10. A method of manufacturing a metal-insulator-metal (MIM) capacitor, comprising:
forming a lower electrode on a surface of a semiconductor substrate;
forming an insulating film on the surface of the semiconductor substrate and a portion of the lower electrode;
forming an upper electrode on a surface of the insulating film above the lower electrode; and
connecting an air bridge wire only to a central region of a surface of the upper electrode, so that the air bridge wire is spaced above an end region of the surface of the upper electrode.

11. The method according to claim 10, wherein the step of forming the insulating film comprises forming the insulating film on the surface of the semiconductor substrate and the lower electrode, and forming an opening in the insulating layer to expose the lower electrode.

12. The method according to claim 11, further comprising:
forming a wire connected to the lower electrode through the opening.

13. The method according to claim 10, wherein the central region of the surface of the upper electrode is generally aligned with a central region of a surface of the lower electrode.

14. The method according to claim 10, wherein each of the upper electrode and the lower electrode comprises a plurality of stacked metal films.

15. The method according to claim 14, wherein the lower electrode comprises Au film, Pt film, and Ti film in this order on the substrate.

16. The method according claim 15, wherein the upper electrode comprises Ti film, Pt film, and Au film in this order on the insulating film.

17. The method according claim 10, wherein each of the upper electrode and the lower electrode has a thickness of about 600 nm to 1 μm.

18. The method according claim 10, wherein the wire has a thickness of about 100 nm to 300 nm.

19. The method according claim 10, wherein the air bridge wire comprises Au.
